(19) United States
(12) Patent Application Publication
(10) Pub. No.: US 2026/0280572 A1
(43) Pub. Date: Sep. 17, 2026

(54) PHASE-LOCKED LOOP AND METHOD

(71) Applicants: CENTRE NATIONAL DE LA RECHERCHE SCIENTIFIQUE, Paris (FR); INSTITUT POLYTECHNIQUE DE BORDEAUX, Talence (FR); UNIVERSITE DE BORDEAUX, Bordeaux (FR); STMicroelectronics International N.V., Geneva (CH)

(72) Inventors: Hélène Esch, Seyssinet Pariset (FR); Guillaume Melas, Grenoble (FR); Philippe Level, Saint Egreve (FR); Jean-Loup Margerin, Vinay (FR); Yann Daniel Marie Deval, TALENCE (FR)

(21) Appl. No.: 19/559,588

(22) Filed: Mar. 6, 2026

(30) Foreign Application Priority Data
Mar. 14, 2025 (FR) FR2502596

(51) Int. Cl. H03L 7/107; H03L 7/089; H03L 7/099; H03L 7/18

(52) U.S. Cl. CPC H03L 7/1075; H03L 7/0891; H03L 7/099; H03L 7/18

(57) ABSTRACT

The present description concerns a phase-locked loop comprising a phase frequency detector receiving a reference frequency and a feedback frequency obtained by division of an output frequency, a charge pump controlled by the phase frequency detector, a low-pass filter receiving an output of the charge pump and delivering an analog control signal, an oscillator delivering the output frequency determined by an analog modulation signal, the analog control signal, and a digital control signal. A digital circuit delivers the digital control signal from the reference and feedback frequencies. A gain of a digital loop comprising the frequency divider and the digital circuit is smaller than or equal to 1 for frequencies lower than a unity frequency of an analog loop comprising the frequency divider, the phase frequency detector, the charge pump, and the analog filter.

### CROSS-REFERENCE TO RELATED APPLICATIONS

This application claims the priority benefit of French Patent Application No. 25/02596 filed on Mar. 14, 2025, entitled “Phase-locked loop,” which is hereby incorporated herein by reference to the maximum extent allowable by law.

### TECHNICAL FIELD

The present disclosure generally concerns electronic circuits and methods, and, more particularly, phase-locked loops and methods.

### BACKGROUND

To transmit data, for example, via a radio frequency wireless communication channel, between a transmitter circuit and a receiver circuit, it is known to use modulations involving a phase or frequency modulation of a carrier frequency. Such modulations involving a phase modulation or a frequency modulation, more generally referred to as frequency modulations, usually use polar transmitters to implement the frequency modulation.

A polar transmitter comprises a phase-locked loop delivering an output frequency. To modulate, or modify, the output frequency from a current value to a next value, so as to pass from a current phase to a next phase, a sequence of successive modifications of the output frequency is applied to the phase-locked loop, each modification of the sequence corresponding to a vector in polar coordinates.

However, in known phase-locked loops, during a phase modification by a sequence of successive modifications of the output frequency, the phase reached at the end of the phase modification exhibits an error with respect to a target phase, which is not desirable. For example, this phase error is particularly troublesome for data transmissions involving a large number of symbols, for example at least sixteen symbols, as is the case with 16-quadrature amplitude modulation (QAM) transmission, which is based on sixteen different symbols.

### SUMMARY

There exists a need to overcome all or part of the disadvantages of known phase-locked loops, for example when these phase-locked loops are used in a polar transmitter.

An embodiment overcomes all or part of the disadvantages of known phase-locked loops, for example when these phase-locked loops are used in a polar transmitter.

An embodiment provides a circuit comprising a phase-locked loop. The phase-locked loop comprises a phase frequency detector configured to receive a reference frequency and a feedback frequency, a charge pump configured to be controlled by an output of the phase frequency detector, an analog low-pass filter configured to receive an output of the charge pump and to deliver an analog control signal, a controllable oscillator configured to deliver an output frequency of the phase-locked loop, a frequency divider configured to receive the output frequency and to deliver the feedback frequency; and a digital circuit configured to receive the reference frequency and the feedback frequency, and to deliver a digital control signal.

The oscillator is configured so that the output frequency is at least partly determined by an analog frequency modulation signal, the analog control signal, and the digital control signal. An analog loop comprises the frequency divider, the phase frequency detector, the charge pump, and the analog filter. A digital loop comprises the frequency divider and the digital circuit. An open-loop gain of the digital loop is smaller than or equal to 1 for low frequencies lower than a unity frequency for which an open-loop gain of the analog loop is unity.

According to an embodiment, the digital loop is configured to only correct an error on the output frequency caused by the analog loop.

According to an embodiment, the phase-locked loop is controlled by the analog loop.

According to an embodiment, the digital circuit can be selectively disabled.

According to an embodiment, the digital circuit comprises a time-to-digital converter receiving the feedback frequency and the reference frequency, and a digital band-pass filter configured to receive an output of the converter and to deliver the digital control signal.

According to an embodiment, the digital band-pass filter is programmable.

According to an embodiment, a modulation of the output frequency is at least partly controlled by the analog modulation signal.

According to an embodiment, the frequency divider is controlled by a digital modulation signal.

According to an embodiment, a modulation of the output frequency is controlled by the analog modulation signal and by the digital modulation signal.

According to an embodiment, the phase-locked loop is configured to implement a two-point frequency modulation.

According to an embodiment, a value of the gain of the analog loop in the bandwidth of the analog loop is at least 30 times greater, preferably 50 times greater, than a value of the gain of the digital loop in the bandwidth of the digital loop.

According to an embodiment, the low frequencies are lower than half the unity frequency, preferably than one fifth of the unity frequency.

According to an embodiment, the unity frequency is in the range from 100 to 900 KHz.

According to an embodiment, the phase-locked loop is adapted to delivering the high output frequency at values higher than 1 GHz.

Another embodiment provides a polar transmitter comprising a circuit such as defined hereabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, schematically and in the form of blocks, an example of a phase-locked loop adapted to implementing a modulation of an output frequency of the phase-locked loop;

FIG. 2 illustrates, in an IQ reference frame, a sequence of modification of the frequency of a phase-locked loop during an example of modulation of an output frequency of a phase-locked loop;

FIG. 3 shows, schematically and in the form of blocks, an embodiment of a phase-locked loop;

FIG. 4 shows, schematically and in the form of blocks, an example of embodiment of a digital circuit of the phase-locked loop of FIG. 3; and

FIG. 5 shows the variation as a function of frequency of a gain of an analog loop and of a gain of a digital loop of the phase-locked loop of FIG. 3.

### DETAILED DESCRIPTION OF ILLUSTRATIVE EMBODIMENTS

The same elements have been designated by the same The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, although embodiments of a phase-locked loop allowing a modulation of an output frequency delivered by the phase-locked loop in the case where the phase-locked loop forms part of a radio frequency transmitter circuit have been described herein, these embodiments of the phase-locked loop can be implemented in any known circuit where a modulation of an output frequency of a phase-locked loop is required.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

FIG. 1 shows, schematically and in the form of blocks, an example of a phase-locked loop 1 adapted to implementing a modulation of an output frequency Fout of phase-locked loop 1.

Phase-locked loop 1 comprises a phase frequency detector (PFD). The PFD circuit is configured to receive a reference frequency Fref, or, in other words, a periodic signal at reference frequency Fref. The PFD circuit is configured to receive a feedback frequency Ffb, or, in other words, a periodic feedback signal at frequency Ffb.

As an example, the PFD circuit has an output configured to indicate whether the signal at frequency Ffb is in phase advance or lag with respect to the signal at frequency Fref. For example, the output of the PFD circuit delivers a first signal Dw indicating when the signal at frequency Ffd is in phase advance with respect to the signal at frequency Fref, and a second signal Up indicating when the signal at frequency Ffd is in phase lag with respect to the signal at frequency Fref.

As an example of implementation, the PFD circuit comprises two synchronous D flip-flops 100 and 102. Each of flip-flops 100 and 102 comprises a D data input. Each of flip-flops 100 and 102 has a clock input Ck configured to receive a clock signal for the flip-flop. Each of flip-flops 100 and 102 comprises a reset input Rst configured to receive a reset signal for the flip-flop. Each of flip-flops 100 and 102 comprises a Q output updated from the D data input of the flip-flop each time the clock signal received by the input Ck of this flip-flop exhibits an active edge to which this input Ck is sensitive, for example at each rising edge of the signal received by this input Ck. The Q output of the flip-flop is reset to an initial state each time the signal received by the input Rst of this flip-flop is in an active state. As an example, the PFD circuit comprises a circuit 104 for resetting flip-flops 100 and 102, configured to receive the Q outputs of flip-flops 100 and 102 and to deliver a reset signal rst to the inputs Rst of flip-flops 100 and 102. For example, circuit 104 is an AND gate receiving signals Up and Dw, and delivering signal rst. Flip-flop 100 receives the signal at frequency Fref on its input Ck and a binary signal in active state ‘1’ on its D input, and delivers signal Up on its Q output. Flip-flop 102 receives the signal at frequency Ffb on its input Ck and an active-state binary signal ‘1’ on its D input, and delivers signal Dw on its Q output.

There exist other known examples of implementation of the PFD phase frequency detector circuit.

Phase-locked loop 1 comprises a charge pump CP. Circuit CP is configured to be controlled by the PFD circuit. For example, charge pump CP is controlled by the output signals Up and Dw of circuit CP. For example, charge pump CP receives signals Up and Dw.

Charge pump CP is configured to deliver a current Icp having a value controlled by the PFD circuit. For example, the value of current Icp is selectively zero, positive, or negative depending on the control of circuit CP by the PFD circuit.

For example, charge pump CP comprises a current source CSup and a switch ITup series-connected between a power supply potential Vdd and an output of circuit CP delivering current Icp, switch ITup being connected between current source CSup and the output of circuit CP, and being controlled by the PFD circuit, for example by the signal Up of the PFD circuit. Current source CSup delivers a positive current ITup to the output of circuit CP when switch ITup is on. Charge pump CP also comprises a current source CSdw and a switch ITdw series-connected between a reference power supply potential GND, for example ground, and the output of circuit CP delivering current Icp, switch ITdw being connected between current source CSdw and the output of circuit CP, and being controlled by circuit PFD, for example by the signal Dw of the PFD circuit. Current source CSdw supplies a negative current ITdw to the output of circuit CP when switch ITdw is on.

Phase-locked loop 1 comprises an analog low-pass filter Flp. Filter Flp is configured to receive the output Icp of charge pump CP, and to deliver a corresponding analog control signal Cmda, for example an analog control voltage Cmda.

As an example, filter Flp comprises a resistor R and a capacitor C1 in series between potential GND and a node 106 coupled, preferably connected, to the output of charge pump CP, as well as a capacitor C2 connected between node 106 and potential GND. Signal Cmda is available on node 106.

Phase-locked loop 1 comprises a controllable oscillator VCO. The VCO oscillator is configured to deliver an output frequency Fout of phase-locked loop 1, that is, to deliver an output signal of loop 1 at frequency Fout.

Frequency Fout is at least partly determined by signal Cmda. For example, the VCO circuit receives signal Cmda.

Further, in this example where loop 1 is adapted to implementing a modulation of its output frequency Fref, the VCO circuit receives an analog frequency modulation signal Mod1. Frequency Fout is then at least partly determined by signal Mod1 in addition to signal Cmda. More particularly, signal Cmda enables to control a central (or set point) value of oscillator frequency VCO, and thus the output frequency of loop 1, and signal Mod1 enables to control a modulation of the frequency of the VCO oscillator, and thus the output frequency of loop 1, around this central (or set point) value. Signal Cmda is an internal signal of loop 1, and thus forms part of loop 1, or, in other words, is delivered by loop 1 itself. However, signal Mod1 is a signal external to the loop, or in other words, is a signal for controlling loop 1. Since signal Mod1 is not an internal signal of loop 1, it is, for example, said to be “out-of-band”.

For example, the central value of the output frequency of loop 1 corresponds to the value of a carrier frequency for data transmission. For example, the central value of the output frequency is equal to several gigahertz, for example substantially equal to 4.8 GHz, preferably equal to 4.8 GHz. For example, signal Mod1 controls a modulation of the output frequency of loop 1 around its central value, this modulation being in the range from a few kilohertz to a few megahertz when the central value is at least one gigahertz, for example 4.8 GHz. The data are transmitted with this frequency modulation.

As an example, the VCO oscillator is an LC oscillator having its output frequency determined by a product L*C of the oscillator, that is, the product of an inductance value L of inductive components of the VCO oscillator by a capacitance value C of capacitive components of the oscillator. For example, the VCO oscillator comprises a first varactor (variable capacitance) controlled by signal Cmda and having a gain Kvco, and a second varactor controlled by signal Mod1 and having a gain Kmod.

Phase-locked loop 1 comprises a frequency divider Fdiv configured to receive output frequency Fout, that is, the signal at frequency Fout available at the output of loop 1, and to deliver feedback frequency Ffb, that is, the feedback signal at frequency Ffb. More particularly, circuit Fdiv is configured so that frequency Ffb is obtained by dividing frequency Fout by a number A. Number A is, for example, a positive integer greater than 1, and preferably a positive decimal number greater than 1.

To modulate frequency Fout, it is known to modulate the output frequency of the VCO circuit with signal Mod1, that is, to modulate the frequency set point or control of the VCO oscillator. However, when high modulation frequencies, for example higher than 1 MHz, are required, the low bandwidth of phase-locked loop 1 may not be sufficient. It is then known to implement a two-point modulation (TPM).

In a two-point modulation, at the same time as (or in parallel with) the modulation of the frequency set point of the VCO circuit by signal Mod1, the number A by which frequency Fout is divided to obtain frequency Ffb is also modulated. For this purpose, as shown in FIG. 1, circuit Fdiv receives a digital modulation signal Mod2. Signal Mod2 controls a modulation of number A. The modulation of number A by signal Mod2 and of the gain of the VCO circuit by signal Mod1 are configured to obtain a targeted modulation of frequency Fout. For example, the modulation of number A by signal Mod2 is configured to cause the same variation (or modulation) of frequency Fout as the modulation of the gain of the VCO circuit by signal Mod1.

Two-point modulation in a phase-locked loop is well known to those skilled in the art and is, for example, described in the paper “An ADPLL with Two-Point Modulation Gain Calibration for 2.4 GHz ISM-Band in 40 nm CMOS” by H. Tang et al, 2023 IEEE International Symposium on Circuits and Systems (ISCAS), Monterey, CA, USA, 2023, pp. 1-4.

In loop 1, during a two-point modulation, there is:—a low-pass path which comprises circuits Fdiv, PFD, CP, Flp, and VCO, and for which a modification of signal Mod2 causes a modification of frequency Fout if the rate of modification of frequency Fout is within the bandwidth of filter Flp, and —a high-pass path which only comprises the VCO circuit, and for which a modification of signal Mod1 causes a modification (modulation) of frequency Fout.

However, two-point modulation generally suffers from a gain offset between the high-pass and low-pass paths, which results, for example, from a gain error in the VCO circuit. This gain error causes a modulation error. For example, signal Mod1 should modulate the output frequency of the VCO oscillator linearly, but this is not the case in practice, for example because the gain of the varactor controlled by signal Mod1 is not constant over the entire range of variation of signal Mod1.

This gain offset causes a modification of frequency Fout which is not that expected for a given modification of signals Mod1 and Mod2.

When loop 1 is used to implement a modulation of frequency Fout for a data transmission, this error between an expected or intended modification of frequency Fout and the modification actually observed in frequency Fout poses a problem.

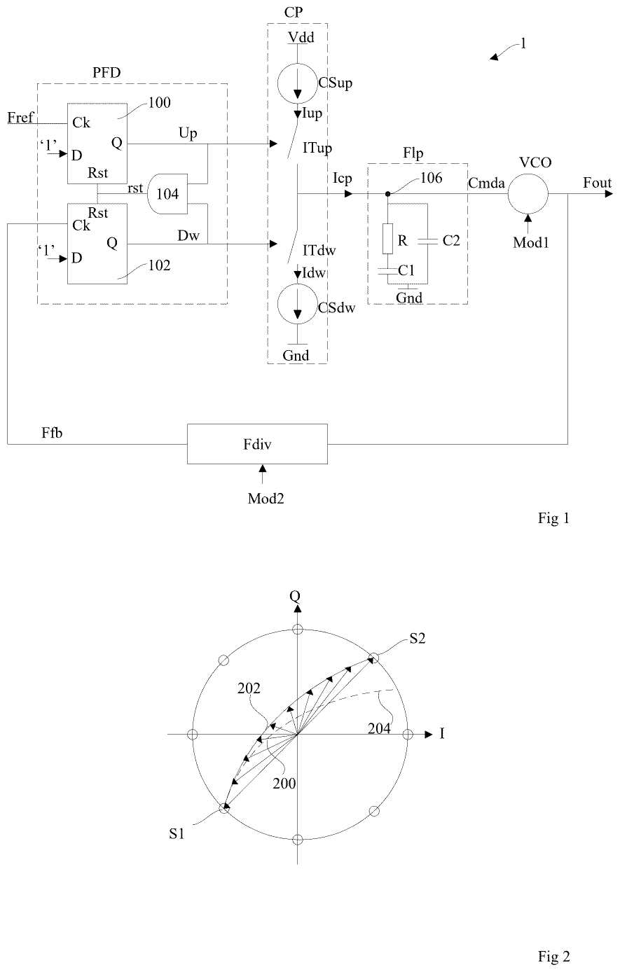

FIG. 2 illustrates, in an IQ reference frame, a sequence of modification of the frequency of a phase-locked loop, for example loop 1 in the drawing, during an example of modulation of an output frequency of the loop.

In this example, the illustrated modulation is a phase-change modulation with 8 symbols, each represented by a circle in FIG. 1.

During a phase modulation to pass from a current (or start) phase corresponding to a symbol S1, to a next (or end) phase corresponding to a symbol S2, a sequence of successive phase modifications is applied to the phase-locked loop. For example, each phase modification in the sequence is implemented by a two-point modulation applied to the loop. In FIG. 2, each phase modification to pass from symbol S1 to symbol S2 is represented by a corresponding vector 200, only one of these vectors being referenced in FIG. 2 so as not to overload it. Each phase modification in the sequence, or, in other words, each vector 200, is determined by a trajectory 202 enabling to pass from symbol S1 to symbol S2.

However, in practice, as indicated in relation with FIG. 1, when a modulation of the output frequency of loop 1 is implemented by applying a sequence of modifications (or deviations) of the output frequency of loop 1, at each modification in the sequence, the gain offset between the low-pass path and the high-pass path of loop 1 results in a phase error. As a result, the trajectory actually followed to pass from one symbol, for example S1, to another, for example S2, is not that expected.

In FIG. 2, an example of such a trajectory 204 which does not correspond to the trajectory 202 expected during the passage from symbol S1 to symbol S2 is illustrated and shown in dotted lines.

During a modulation of the output frequency of a phase-locked loop, to limit the error for each modification of a modification sequence applied to the output frequency, it could be considered increasing the bandwidth of the phase-locked loop by modifying filter Flp.

However, increasing the bandwidth of the loop by modifying filter Flp can lead to noise of a sigma-delta modulator of circuit Fdiv, when circuit Fdiv comprises such a modulator, ending up in the bandwidth of the loop, which is not desirable. Further, increasing the bandwidth of the loop can lead to noise from a circuit delivering reference frequency Fref and/or noise originating from circuits PFD and CP ending up in the bandwidth of loop 1, which is not desirable.

Further, modifying analog filter Flp is generally not simple, since filter Flp also needs to be sized to ensure the stability of the phase-locked loop.

On the other hand, when the phase-locked loop is used in a transmitter and needs to allow a plurality of types of transmission, for example transmissions designated by the acronyms BLE, HDT, or QAM-type transmissions such as the 16-QAM transmission, a plurality of corresponding configurations of filter Flp then have to be provided, which leads to an increase in the surface area occupied by the phase-locked loop, and, further, can be difficult to implement.

It is here provided to add, in phase-locked loop 1, a digital circuit configured to modulate the frequency set point of the VCO oscillator, so as to correct the error on frequency Fout upon modification of this frequency Fout, for example upon each modification of the frequency Fout of a sequence of modifications to implement a frequency or phase modulation of frequency Fout. The digital circuit controls the oscillator based on a phase difference between signals Fref and Fdiv. The provided digital circuit then forms, together with circuits Fdiv and VCO, a digital loop. This digital loop operates in parallel with the analog loop comprising circuits Fdiv, PFD, CP, Flp, and VCO.

The open-loop gain of the digital loop is smaller than or equal to 1 for low frequencies as compared with a unity frequency for which an open-loop gain of the analog loop is unity. Thus, the provided digital circuit does not modify the low-frequency operation of the phase-locked loop. As an example, frequencies are said to be low with respect to the unity frequency of the analog loop when these frequencies are smaller than half the unity frequency, for example smaller than one fifth of the unity frequency. As an example, the unity frequency is in the range from 100 to 900 KHz.

For example, and more generally, the digital loop is said to be a broadband loop, while the analog loop is said to be a narrowband loop. In other words, the digital loop is configured to correct a modulation error more quickly than the analog loop. Still in other words, as an example, frequencies belonging to the bandwidth of the digital loop are higher than frequencies belonging to the bandwidth of the analog loop.

For example, the digital loop is configured to correct only one error on the output frequency which is caused by, or results from, the analog loop. The provided digital circuit enables, in two-point modulation, to correct the modulation error resulting from the gain offset between the low-pass and high-pass paths.

According to an embodiment, the gain of the analog loop in its bandwidth is greater, for example at least 30 times greater, or even 50 times greater, than the gain of the digital loop in its bandwidth. Thereby, the digital loop does not disturb the operation of the analog loop, and, more generally, the operation of the phase-locked loop. Indeed, the digital circuit is a circuit for correcting the modulation error of the output frequency Fout of the phase-locked loop, but the locking of the phase-locked loop remains performed by the analog loop. In other words, the locking of the phase-locked loop is controlled by the analog loop, the digital loop only having an error-correction role once the phase-locked loop has been locked.

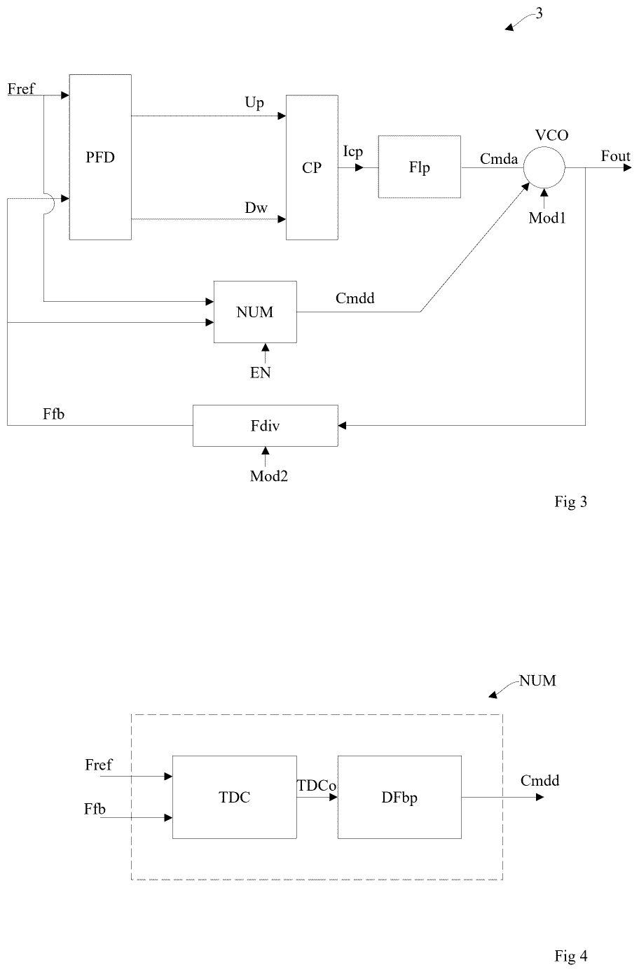

FIG. 3 shows an example of embodiment of a phase-locked loop 3 comprising such a digital circuit NUM.

Phase-locked loop 3 comprises all the elements of the phase-locked loop 1 described in relation with FIG. 1. Thus, unless indicated otherwise, all that has been indicated for phase-locked loop 1 applies to phase-locked loop 3.

Phase-locked loop 3 further comprises a digital circuit NUM such as described hereabove.

Circuit NUM is configured to receive frequency Fref, or, in other words, the signal at frequency Fref, and signal Ffb, or, in other words, the feedback signal at frequency Ffb. Circuit NUM is configured to deliver a digital control signal Cmdd.

Signal Cmdd is, for example, determined based on signals Ffb and Fref. For example, signal Cmdd is determined by a phase difference between signals Fref and Ffb.

Preferably, signal Cmdd is determined by a digital signal indicating a value of the phase difference between signals Fref and Ffb, to which a band-pass digital filtering is applied. The provision of a band-pass filter prevents the digital loop from interfering with the operation of loop 3 at low frequencies. The provision of a band-pass filter also enables to limit the introduction of noise into loop 3 at high frequencies, for example the quantization noise of a sigma-delta modulator of circuit Fdiv.

Thus, in phase-locked loop 3, the set point value of frequency Fout is determined by frequency Fref and by the value of number A, the modulation of frequency Fout around its set point value is determined by signals Mod1 and Mod2 (two-point modulation) respectively modulating the frequency set point of the VCO oscillator and the value of number A, and the correction of the modulation error is ensured by signal Cmdd.

In other words, the VCO oscillator is configured so that frequency Fout is determined by set point signal Cmda, modulation signals Mod1 and Mod2, and digital error correction signal Cmdd.

Signals Cmdd, Cmda, and Mod1 are signals for controlling the oscillator. For example, signals Mod1 and Cmdd enable to modulate the gain of the VCO oscillator, and signal Cmda controls, for each gain value of the VCO oscillator, the value of frequency Fout.

Optionally, as shown in FIG. 3, circuit NUM may be selectively disabled. For example, circuit NUM receives a binary signal EN having its state determining whether circuit NUM is enabled or disabled.

An advantage of the fact that circuit NUM can be selectively disabled is that it can be switched off (disabled) when loop 3 is used to deliver a frequency Fout of given value, but without frequency modulation being applied to frequency Fout. This is the case, for example, when loop 3 is used as a frequency generator, or, in other words, to implement a frequency synthesis.

Another advantage of the fact that circuit NUM can be selectively disabled is that this circuit can be switched off (disabled) when the electronic system comprising loop 3 is not in a data transmission phase, which enables to decrease the power consumption of loop 3, and thus of the electronic system.

Still another advantage of the fact that circuit NUM can be selectively disabled is that it can be switched off (disabled) when the electronic system comprising loop 3 is in a data reception phase, which enables to decrease the noise. Indeed, since the digital loop is a broadband loop, it can transmit noise originating from a sigma-delta modulator of circuit DIV, noise originating from a circuit delivering frequency Fref, and the specific noise of the digital loop.

The fact that circuit NUM can be disabled and that loop 3 still remains functional for use as a generator of frequency Fout with no frequency modulation shows that loop 3 is not a simple, known analog/digital hybrid phase-locked loop. Indeed, in known hybrid phase-locked loops, removing or disabling the digital loop makes, for example, the phase-locked loop inoperative, that is, the phase-locked loop is, for example, no longer able to lock.

Preferably, circuit NUM, and more generally the digital loop comprising circuit NUM, are configured to control variations of frequency Fout smaller than or equal to 10% of the maximum value of variation of the frequency Fout that loop 3 is configured to receive at each modification of the frequency Fout of a sequence of successive modifications of the frequency Fout applied to loop 3 during a modulation of frequency Fout.

For example, loop 3 is configured to deliver a frequency Fout having frequency values higher than 1 GHz. In such a case, each modification of a sequence of modification of frequency Fout to pass from a current phase to a next phase corresponds to a frequency deviation having, for example, a maximum value in the order of 20 MHz.

FIG. 4 shows, schematically and in the form of blocks, an example of embodiment of an implementation of circuit NUM.

In this example, circuit NUM comprises a circuit TDC configured to deliver a digital signal TDCo, for example a digital code over a plurality of bits, indicating a phase shift value between signals Fref and Ffb received by this circuit TDC from circuit NUM. As an example, circuit TDC is a time-to-digital converter.

In this example, circuit NUM comprises a digital band-pass filter DFbp. Filter DFbp is configured to apply a band-pass filtering to signal TDCo, and to deliver the signal Cmdd resulting from this band-pass filtering.

Optionally, filter DFbp is programmable. This enables to adapt the bandwidth of filter DFbp, and thus of the digital loop, according to the type of modulation used.

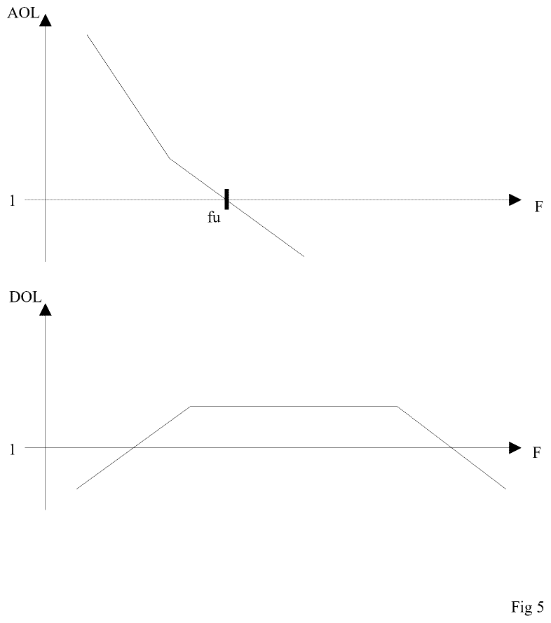

FIG. 5 shows the variation as a function of frequency F of the open-loop gain AOL of the analog loop of circuit 3 in FIG. 3, and of the open-loop gain DOL of the digital loop of circuit 3 of FIG. 3. Gains AOL and DOL are in logarithmic scale.

The variation of gain AOL, respectively DOL is shown at the top, respectively at the bottom, of FIG. 5.

As can be seen in FIG. 5, gain AOL is high for low frequencies F, for example frequencies F smaller than fu/2 or even than fu/5, with fu the unity frequency of the analog loop for which gain AOL is equal to 1.

Conversely, for low frequencies F, there is no gain DOL, or, in other words, gain DOL is smaller than or equal to 1.

Further, gain DOL is, in the bandwidth of the digital loop, low as compared with gain AOL in the bandwidth of the analog loop, for example at least 30 times lower or even 50 times lower.

As an example, the frequency fu of the analog loop is in the range from 100 to 900 KHz.

Embodiments and variants of embodiments of phase-locked loop 3 have been described hereabove, in which loop 3 implements a two-point modulation. Thus, in these embodiments and variants, the value of frequency Fout is determined by signal Cmda (and thus by the value of Fref and the value of A), the modulation of frequency Fout is determined by analog modulation signal Mod1 and by digital modulation signal Mod2, and the correction of the modulation error resulting from the gain offset between the low-pass and high-pass paths is determined by circuit Cmdd.

However, in other embodiments, not shown, the phase-locked loop implements a single-point modulation (or one-point modulation). In this case, number A is not modulated based on signal Mod2, and only the frequency set point of the VCO oscillator is modulated by signal Mod1. Frequency divider DIV then does not receive signal Mod2.

In such a case of a single-point modulation, signal Cmdd does not correct a modulation error resulting from a gain difference between the low-pass and high-pass paths of phase-locked loop 3, but directly acts on the modulation to correct the modulation itself.

In such a case of a single-point modulation, the output frequency is determined by signal Mod1, signal Cmda, and signal Cmdd. Further, the frequency modulation is controlled by signal Mod1.

Thus, whether phase-locked loop 3 is controlled in single-point modulation or in two-point modulation, the value of frequency Fout is at least partly determined by signal Cmda, signal Mod1, and signal Cmdd. Further, the modulation of frequency Fout is at least partly determined by signal Mod1.

Various embodiments and variants have been described. Those skilled in the art will understand that certain features of these various embodiments and variants may be combined, and other variants will occur to those skilled in the art. In particular, although this has not been illustrated and detailed, those skilled in the art will be capable of providing a polar transmitter circuit comprising phase-locked loop 3 and, for example, a control circuit configured to deliver signal Mod1, and signal Mod2 when the latter is present, so as to implement a sequence of successive modifications of frequency Fout corresponding to a modulation of frequency Fout.

Finally, the practical implementation of the described embodiments and variants is within the abilities of those skilled in the art based on the functional indications given hereabove. In particular, as for the implementations of circuits PFD, CP, Flp, and NUM, they are not limited to the described examples, and those skilled in the art will be capable of providing other implementations for each of these circuits, as long as these other implementations lead to circuits operating as described hereabove. Further, those skilled in the art will be capable of implementing circuit Fdiv.

What is claimed is:

1. A circuit comprising a phase-locked loop, the phase-locked loop comprising:
a phase frequency detector configured to receive a reference frequency and a feedback frequency;
a charge pump configured to be controlled by an output of the phase frequency detector;
a low-pass analog filter configured to receive an output of the charge pump and to deliver an analog control signal;
a controllable oscillator configured to deliver an output frequency of the phase-locked loop;
a frequency divider configured to receive the output frequency and to deliver the feedback frequency;
a digital circuit configured to receive the reference frequency and the feedback frequency, and to deliver a digital control signal;
the controllable oscillator configured so that the output frequency is at least partly determined by an analog frequency modulation signal, the analog control signal, and the digital control signal;
an analog loop comprising the frequency divider, the phase frequency detector, the charge pump, and an analog filter; and
a digital loop comprising the frequency divider and the digital circuit, wherein an open-loop gain of the digital loop is smaller than or equal to 1 for low frequencies lower than a unity frequency for which an open-loop gain of the analog loop is equal to 1.

2. The circuit of claim 1, wherein the digital loop is configured to only correct an error on the output frequency caused by the analog loop.

3. The circuit of claim 1, wherein a locking of the phase-locked loop is controlled by the analog loop.

4. The circuit of claim 1, wherein the digital circuit is selectively disable-able.

5. The circuit of claim 1, wherein the digital circuit comprises a time-to-digital converter configured to receive the feedback frequency and the reference frequency, and a band-pass digital filter configured to receive an output of the time-to-digital converter and to deliver the digital control signal.

6. The circuit of claim 5, wherein the band-pass digital filter is programmable.

7. The circuit of claim 1, wherein a modulation of the output frequency is at least partly controlled by the analog frequency modulation signal.

8. The circuit of claim 1, wherein the frequency divider is controlled by a digital modulation signal.

9. The circuit of claim 8, wherein a modulation of the output frequency is controlled by the analog frequency modulation signal and by the digital modulation signal.

10. The circuit of claim 8, wherein the phase-locked loop is configured to implement a two-point frequency modulation.

11. The circuit of claim 1, wherein a value of a gain of the analog loop in a bandwidth of the analog loop is at least 30 times greater than a value of a gain of the digital loop in a bandwidth of the digital loop.

12. The circuit of claim 1, wherein the low frequencies are lower than half the unity frequency.

13. The circuit of claim 1, wherein the unity frequency is in a range from about 100 KHz to about 900 KHz.

14. The circuit of claim 1, wherein the phase-locked loop is adapted to delivering the output frequency at values higher than about 1 GHz.

15. The circuit of claim 1, wherein the circuit is a polar transmitter comprising the phase-locked loop.

16. A method of operating a phase-locked loop, the method comprising:
receiving, by a phase frequency detector, a reference frequency and a feedback frequency;
controlling, by an output of the phase frequency detector, a charge pump;
receiving, by a low-pass analog filter, an output of the charge pump;
delivering, by the low-pass analog filter, an analog control signal;
delivering, by a controllable oscillator, an output frequency of the phase-locked loop;
receiving, by a frequency divider, the output frequency;
delivering, by the frequency divider, the feedback frequency;
receiving, by a digital circuit, the reference frequency and the feedback frequency;
delivering, by the digital circuit, a digital control signal; and
determining, by the controllable oscillator, the output frequency at least partly by an analog frequency modulation signal, the analog control signal, and the digital control signal;
wherein an open-loop gain of a digital loop is smaller than or equal to 1 for low frequencies lower than a unity frequency for which an open-loop gain of an analog loop is equal to 1, the digital loop comprising the frequency divider and the digital circuit, and the analog loop comprising the frequency divider, the phase frequency detector, the charge pump, and an analog filter.

17. The method of claim 16, further comprising correcting, by the digital loop only an error on the output frequency caused by the analog loop.

18. The method of claim 16, further comprising controlling, by the analog loop, a locking of the phase-locked loop.

19. The method of claim 16, further comprising selectively disabling the digital circuit.

20. The method of claim 16, further comprising:
receiving, by a time-to-digital converter of the digital circuit, the feedback frequency and the reference frequency;
receiving, by a band-pass digital filter, an output of the time-to-digital converter; and
delivering, by the band-pass digital filter, the digital control signal.
